(19) United States
(12) Patent Application Publication
(10) Pub. No.: US 2007/0178690 A1
(43) Pub. Date: Aug. 2, 2007

(54) SEMICONDUCTOR DEVICE COMPRISING A METALLIZATION LAYER STACK WITH A POROUS LOW-K MATERIAL HAVING AN ENHANCED INTEGRITY

(76) Inventors: Markus Nopper, Dresden (DE); Udo Nothelfer, Radebeul (DE); Axel Preusse, Radebeul (DE)

Correspondence Address: J. Mike Amerson, Williams, Morgan & Amerson, P.C., Suite 1100, 10333 Richmond, Houston, TX, 77042, US

(21) Appl. No.: 11/538,464

(22) Filed: Oct. 4, 2006

(30) Foreign Application Priority Data
Jan. 31, 2006 (DE) 10 2006 004 429.0

(51) Int. Cl. H01L 21/4763; H01L 21/31

(52) U.S. Cl. 438/618; 438/789; 257/E23.144

(57) ABSTRACT

By using a patterned sacrificial layer for forming highly conductive metal regions, the formation of a reliable conductive barrier layer may be accomplished prior to the actual deposition of a low-k dielectric material. Hence, even highly porous dielectrics may be used in combination with highly conductive metals, substantially without compromising the diffusion characteristics and the electromigration performance. Hence, metallization layers for highly scaled semiconductor devices having critical dimensions of 50 nm and significantly less may be provided.

### BACKGROUND OF THE INVENTION

1. Field of the Invention

Generally, the present invention relates to the fabrication of integrated circuits, and, more particularly, to the formation of metallization layers of reduced permittivity by using low-k dielectric materials.

2. Description of the Related Art

In an integrated circuit, a very large number of circuit elements, such as transistors, capacitors, resistors and the like, are formed in or on an appropriate substrate, usually in a substantially planar configuration. Due to the large number of circuit elements and the required complex layout of advanced integrated circuits, the electrical connections of the individual circuit elements are generally not established within the same level on which the circuit elements are manufactured. Typically, such electrical connections are formed in one or more additional “wiring” layers, also referred to as metallization layers. These metallization layers generally include metal-containing lines, providing the inner-level electrical connection, and also include a plurality of inter-level connections, also referred to as vias, filled with an appropriate metal. The vias provide electrical connection between two neighboring stacked metallization layers, wherein the metal-containing lines and vias may also be commonly referred to as interconnect structures.

Due to the ongoing demand for shrinking the feature sizes of highly sophisticated semiconductor devices, highly conductive metals, such as copper and alloys thereof, in combination with a low-k dielectric material, have become a frequently used alternative in the formation of metallization layers. Typically, a plurality of metallization layers stacked on top of each other is necessary to realize the connections between all internal circuit elements and I/O (input/output), power and ground pads of the circuit design under consideration. For extremely scaled integrated circuits, the signal propagation delay, and thus the operating speed, of the integrated circuit may no longer be limited by the field effect transistors but may be restricted, owing to the increased density of circuit elements requiring an even more increased number of electrical connections, by the close proximity of the metal lines, since the line-to-line capacitance is increased, which is accompanied by the fact that the metal lines have a reduced conductivity due to a reduced cross-sectional area. For this reason, traditional dielectrics such as silicon dioxide (k>3.6) and silicon nitride (k>5) are replaced by dielectric materials having a lower permittivity, which are therefore also referred to as low-k dielectrics having a relative permittivity of 3 or less. The reduced permittivity of these low-k materials is frequently achieved by providing the dielectric material in a porous configuration, thereby offering a k-value of significantly less than 3.0. Due to the intrinsic properties, such as a high degree of porosity, of the dielectric material, however, the density and mechanical stability or strength may be significantly less compared to the well-approved dielectrics silicon dioxide and silicon nitride.

During the formation of copper-based metallization layers, a so-called damascene or inlaid technique is usually used, due to copper's characteristic of not forming volatile etch products when being exposed to well-established anisotropic etch ambients. In addition, copper may also not be deposited with high deposition rates on the basis of well-established deposition techniques usually used for aluminum, such as chemical vapor deposition (CVD). Thus, in the inlaid technique, therefore, the dielectric material is patterned to receive trenches and/or vias, which are subsequently filled with the metal by an efficient electrochemical deposition technique. During the etch process, the porous low-k material may be damaged, thereby further reducing the mechanical integrity thereof. The etch damage, in combination with a high number of additional surface irregularities in the form of tiny cavities due to the porosity, may require a post-etch treatment for “sealing” the low-k material prior to filling in the metal. Moreover, a barrier layer is usually formed on exposed surface portions of the dielectric material prior to filling in the metal, which provides the desired adhesion of the metal to the surrounding dielectric material and also suppresses copper diffusion into sensitive device areas as copper may readily diffuse in a plurality of dielectric materials, in particular in porous low-k dielectrics. Furthermore, the performance of the metal lines and vias with respect to stress-induced metal migration, such as electromigration, may strongly depend on the characteristics of an interface between the metal and the dielectric material, thus rendering a reliable coverage of the porous dielectric material an important aspect for the performance of the metallization layer. The reliable coverage of exposed surfaces of a porous material within high aspect ratio openings, typically required in sophisticated applications involving feature sizes of approximately 50 nm and less, by presently established barrier deposition techniques, such as sputter deposition and the like, may not be a straightforward development and hence may significantly degrade production yield and product reliability.

In view of the situation described above, there exists a need for an improved technique that enables the manufacturing of advanced semiconductor devices while avoiding one or more of the problems identified above or at least reducing the effects thereof.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique for forming a metal region in a low-k dielectric material with enhanced integrity of the resulting metallization layer even for materials having a high degree of porosity, as may typically be used for dielectric materials having a relative permittivity of 3.0 and significantly less. In order to obtain a reliable confinement of the metal, such as copper, copper alloys and the like, a conductive barrier layer is formed on surface portions of the metal prior to forming the low-k dielectric material. In this way, a reliable interface between the metal and the low-k dielectric material is provided, wherein the enhanced interface integrity may result in an increased resistance against electromigration while effectively reducing a diffusion of metal atoms into the dielectric and dielectric material into the metal region. In some illustrative embodiments, the confinement of a highly conductive metal, such as copper or copper alloys, by means of a conductive barrier layer may be accomplished on the basis of a sacrificial layer, which may be removed after the formation of corresponding metal regions. By using the sacrificial layer, a high degree of process compatibility with existing inlaid technologies may be maintained.

According to one illustrative embodiment of the present invention, a method comprises forming an opening in a sacrificial layer formed above a substrate of a semiconductor device. The method further comprises forming a metal region in the opening and removing the sacrificial layer. Finally, a low-k dielectric material is formed so as to embed the metal region in the low-k dielectric material.

According to another illustrative embodiment of the present invention, a method comprises forming a metal region above a substrate of a semiconductor device, wherein the metal region has a conductive barrier layer formed on at least a sidewall surface of the metal region. Moreover, a low-k dielectric layer is formed on the conductive barrier layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1j schematically illustrate cross-sectional views of a semiconductor device during the formation of a metallization layer including the low-k dielectric material according to illustrative embodiments of the present invention;

FIGS. 2a-2f schematically depict cross-sectional views of a semiconductor device during the formation of a metallization layer for confining a highly conductive metal region prior to forming a low-k dielectric material, wherein a high degree of process compatibility with existing inlaid technology is maintained; and

FIGS. 3a-3b schematically illustrate cross-sectional views of a semiconductor device during the formation of metal lines and vias in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i. e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention relates to a technique in which a highly conductive metal, such as copper, copper alloys, silver and the like, may be formed on the basis of well-established electrochemical deposition techniques, such as electroless plating, electroplating and the like, wherein the enclosure and thus confinement of the highly conductive material is accomplished on the basis of a conductive barrier layer formed prior to the formation of any low-k dielectric material. To this end, a sacrificial layer may be formed and may be correspondingly patterned to act as a corresponding deposition mask for the electrochemical deposition of the metal. The characteristics of the sacrificial layer may be selected on the basis of process requirements, i.e., the material of the sacrificial layer may be any appropriate material having, in some illustrative embodiments, a significantly reduced porosity compared to a low-k dielectric material, thereby enabling the formation of a highly reliable barrier layer prior to the deposition of the actual low-k dielectric material. In still other illustrative embodiments, the material characteristics of the sacrificial layer may not necessarily require a material of low porosity and may be selected with respect to other characteristics, such as selectivity during an etch process for removing the sacrificial layer, mechanical stability during a chemical mechanical polishing (CMP) process, deposition characteristics, the capability of being patterned by alternative patterning techniques, such as imprint techniques, and the like.

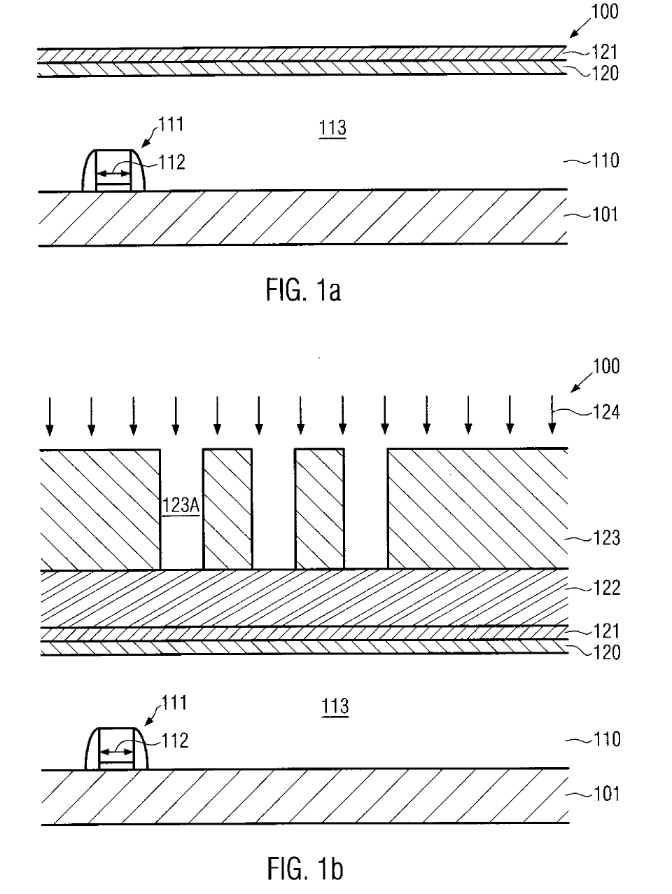

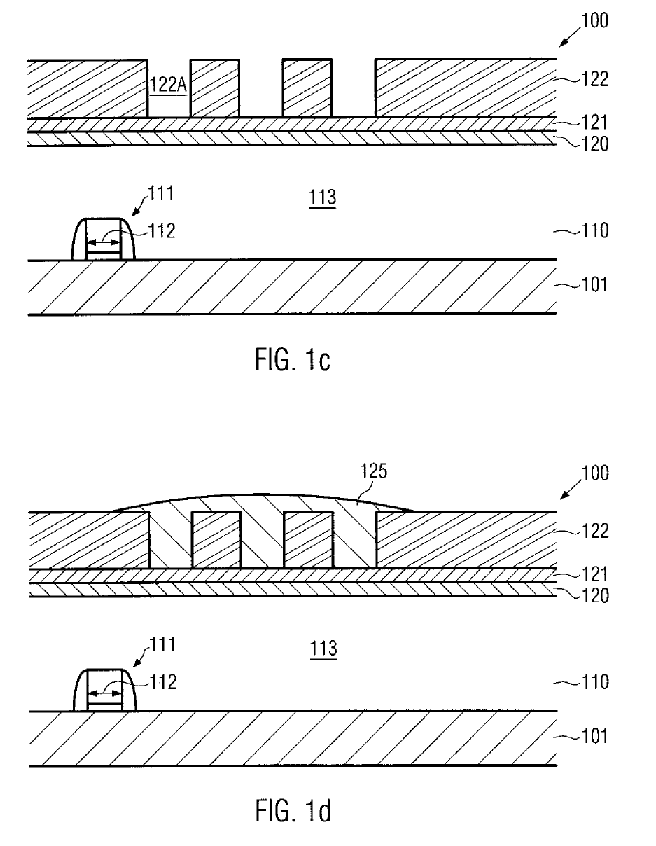

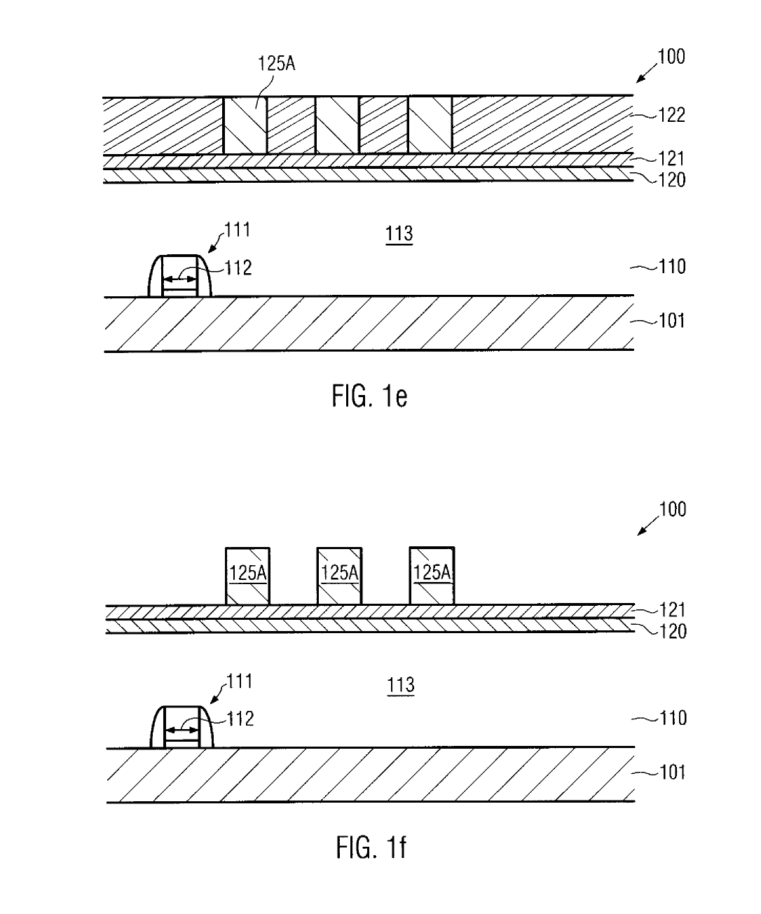

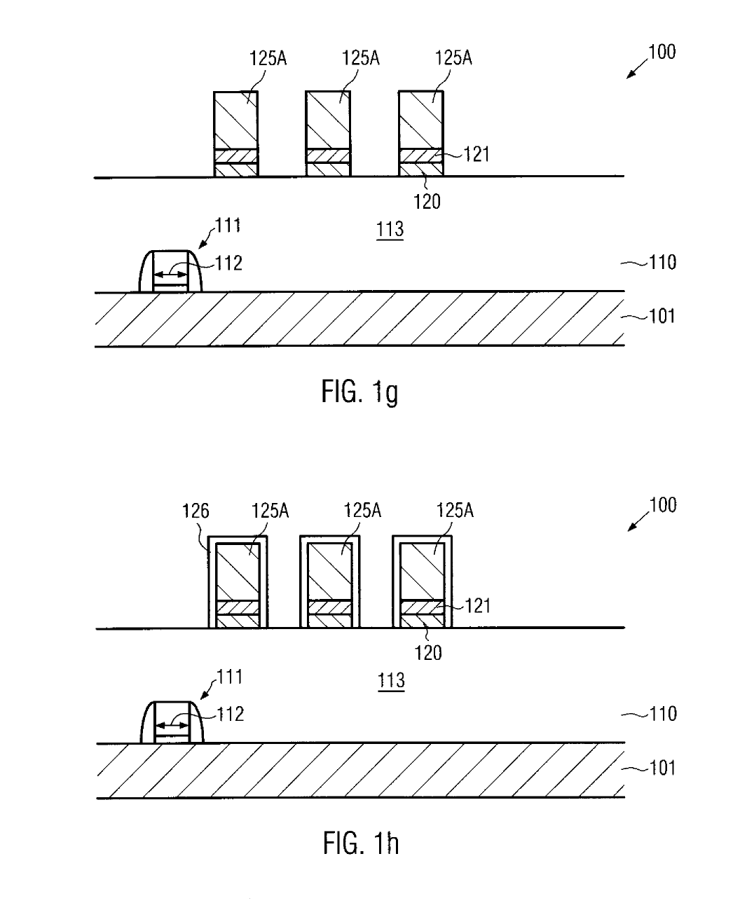

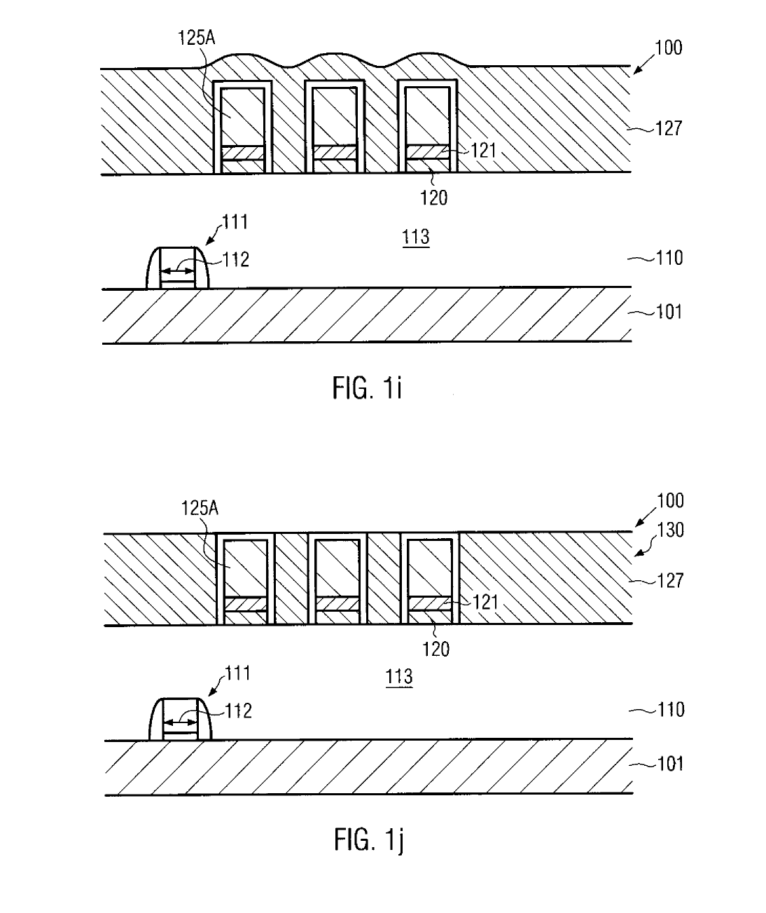

With reference to FIGS. 1a-1j, 2a-2f and 3a-3b, further illustrative embodiments of the present invention will now be described in more detail. FIG. 1a schematically illustrates a cross-sectional view of a semiconductor device 100, which comprises a substrate 101 that may represent any appropriate substrate for the formation of circuit elements therein and thereon. For example, the substrate 101 may represent a bulk silicon substrate, a silicon-on-insulator (SOI) substrate, or any other carrier material having formed thereon a semiconductor layer (not shown) appropriate for the formation of circuit elements, such as transistors, capacitors, resistors and the like. For convenience, a single transistor element 111 embedded in a dielectric layer 113 is illustrated in a device layer 110, wherein, in illustrative embodiments, the circuit element 111 may represent features having a critical dimension of 50 nm and significantly less. For example, the transistor element 111 may have a gate length 112 of 50 nm and significantly less. As previously explained, for highly sophisticated integrated circuits comprising circuit elements 111 with dimensions as indicated before, the performance of the device 100 is substantially determined by the signal propagation delay caused by additional wiring layers, i.e., metallization layers, that are formed above the device layer 110 to electrically connect the individual circuit elements 111. The dielectric layer 113 of the device layer 110 may be comprised of any appropriate dielectric materials, such as silicon dioxide, silicon nitride, silicon oxynitride, or even low-k dielectrics, and the like. Moreover, contact plugs (not shown) may be formed within the device layer 110 to provide contact areas for electrical connection to metallization layers still to be formed.

Furthermore, the semiconductor device 100 may comprise a conductive barrier layer 120 formed above the device layer 110, wherein, in one illustrative embodiment, a seed layer 121 may be formed on the barrier layer 120. The conductive barrier layer 120 may be comprised of any appropriate material having required adhesion and barrier characteristics with respect to a highly conductive metal, such as copper, copper alloy, silver and the like, that is used for the formation of metal lines and regions still to be formed above the barrier layer 120. For example, tantalum, tantalum nitride, tungsten nitride, compounds comprising cobalt, tungsten, phosphorous, compounds comprising cobalt, tungsten, boron and the like may represent appropriate barrier and adhesion materials for a copper-based metal region. In one illustrative embodiment, the barrier layer 120 may be comprised of an appropriate material, which may also act as a seed layer or catalyst layer in a subsequent electrochemical process. In this case, the seed layer 121 may not be necessary and may be omitted. In other illustrative embodiments, the seed layer 121 may be provided in the form of any appropriate material, such as copper, a copper alloy and the like. In one illustrative embodiment, the barrier layer 120 and the seed layer 121, if provided, may be comprised of a material having a moderately low specific resistance of, for instance, 100 μOhm-cm or less so as to not significantly affect the performance of a metal region to be formed above the barrier layer 120. Furthermore, in some illustrative embodiments, the material of the barrier layer 120 and of the seed layer 121, if provided, may be chosen to be less noble than the material deposited above the barrier and the seed layers 120, 121, such as copper and the like. In this case, the seed layer 121 and the barrier layer 120 may be highly efficiently removed in a later manufacturing stage on the basis of an electrochemical etch process, as will be described later on in more detail.

A typical process flow for forming the semiconductor device 100 as shown in FIG. 1a may comprise the following processes. After the formation of the circuit elements 111, any appropriate dielectric material may be deposited to form the dielectric layer 113 for confining and passivating the circuit elements 111. For dielectric materials, such as silicon nitride, silicon oxynitride, silicon dioxide and the like, respective deposition recipes are well-established in the art. For example, silicon nitride may be deposited on the basis of well-established plasma enhanced chemical vapor deposition (PECVD) techniques, while silicon dioxide may be formed from TEOS on the basis of established high-density plasma chemical vapor deposition or sub-atmospheric deposition techniques. Thereafter, any appropriate planarization techniques, such as CMP, may be used in order to provide a substantially planar surface topography. Thereafter, respective contact plugs (not shown) may be formed on the basis of established contact technologies.

Next, the conductive barrier layer 120 may be formed by any appropriate deposition technique, such as CVD, atomic layer deposition (ALD), electroless deposition, any combination thereof and the like. For example, for a plurality of barrier materials, such as tantalum, tantalum nitride and the like, CVD techniques and sputter deposition techniques are well-established in the art. In other cases, an appropriate catalyst material may be deposited or may otherwise be incorporated into the device layer 110, which may then be used as a catalyst material for a subsequent electroless deposition of a barrier material, such as a compound including cobalt/tungsten/phosphorous (CoWP), cobalt/tungsten/boron (CoWB) and the like. In some illustrative embodiments, an additional catalyst material, such as palladium, platinum and the like, may be incorporated into the barrier layer 120, at least in a surface portion thereof, to act as a catalytic material for an electroless deposition of a highly conductive material, such as copper, copper alloys, silver, silver alloys and the like.

Next, the seed layer 121, if desired, may be formed on the basis of any well-established deposition technique, such as sputter deposition, electroless deposition and the like. It should be appreciated that the layers 120 and 121 may be provided with high uniformity due to the substantially planar surface topography, thereby providing the potential for depositing the layers 120 and 121 with reduced thickness, for instance ranging from approximately 5-20 nm, while still maintaining a reliable coverage of the device layer 110.

FIG. 1b schematically illustrates the semiconductor device 100 in a further advanced manufacturing stage. In the embodiment illustrated, the device 100 further comprises a sacrificial layer 122 formed above the barrier and seed layers 120, 121, followed by a resist mask 123 including a plurality of openings 123A, which are dimensioned in accordance with target dimensions of a metal region to be formed above the device layer 110. In some illustrative embodiments, the sacrificial layer 122 may represent any appropriate material, such as silicon dioxide, silicon oxynitride and the like, whereas, in other illustrative embodiments, the sacrificial layer 122 may represent any appropriate polymer material that may allow an efficient patterning on the basis of the resist mask 123. In still other illustrative embodiments, the sacrificial layer 122 may itself be provided in the form of a resist layer, which may then be patterned similarly as the resist mask 123 to act as a deposition mask for the subsequent deposition of a highly conductive metal, when the material characteristics of the resist material are appropriate for providing the desired mechanical stability and integrity during the further processing of the device 100. The sacrificial layer 122 may be formed on the basis of well-established deposition techniques, such as chemical vapor deposition, spin-on techniques, when viscous polymer materials are considered, which may be subsequently cured by heat, radiation and the like. If the resist mask 123 is provided for patterning the sacrificial layer 122, well-established lithography techniques may be used in combination with well-known pre- and post-lithography treatments for forming the resist mask 123. It should be appreciated that, depending on the dimensions of the openings 123A, highly advanced lithography techniques may have to be used, possibly including the provision of anti-reflective coatings (ARC) and the like according to well-established principles.

Irrespective of whether the sacrificial layer 122 itself may be patterned or the additional resist mask 123 is provided, the device 100 is then subjected to a patterning process 124, which may be designed as an anisotropic etch process for transferring the openings 123A into the sacrificial layer 122. In other cases, the process 124 may represent a development process, when the sacrificial layer 122 is provided in the form of a resist layer. In other illustrative embodiments, the patterning of the sacrificial layer 122 may be performed on the basis of mechanical imprint techniques, also referred to as nano-imprint or nano-indentation techniques, in which a “nano” stamp may be provided and may be brought into contact with the layer 122, which may still be in a viscous state, thereby allowing the penetration of the nano-stamp into the layer 122. In other techniques, a corresponding stamp may be provided prior to the formation of the sacrificial layer 122, which may then be deposited in a highly viscous state so as to fill any spaces between the respective nano-stamps. For example, a negative image of the resist layer 123 may be provided in the form of a corresponding nano-template, which may then be introduced into the layer 122, or the nano-template may first be applied so as to contact the layer 121, while subsequently material for the layer 122 is supplied by any appropriate deposition technique. Thereafter, the nano-template may be removed by any appropriate technique, such as selective etching, mechanically withdrawing the template and the like, thereby creating respective openings in the sacrificial layer 122.

FIG. 1c schematically illustrates the semiconductor device 100 after the completion of the above-described process sequence. Hence, the device 100 comprises the patterned sacrificial layer 122 having formed therein openings 122A, which substantially correspond to the openings 123A. It should be appreciated that, depending on the patterning process for forming the openings 122A, additional etch and cleaning steps may be performed to remove any residuals of the layer 122 from the bottom of the openings 122A. For example, if any imprint techniques may have been used for forming the openings 122A, a corresponding cleaning process may be performed after curing the layer 122 and removing the corresponding nano-template. Thereafter, a highly conductive metal, such as copper, a copper alloy, silver, a silver alloy and the like, may be deposited into the openings 122A. For this purpose, an electroless deposition process may be used, wherein the barrier layer 120 or the seed layer 121, if provided, may act as a catalyst layer for initiating a metal deposition upon contact with an appropriate metal electrolyte. In other illustrative embodiments, the deposition of a corresponding metal may be achieved on the basis of an electroplating process, wherein the barrier layer 120 and the seed layer 121 may act as an efficient current distribution layer, which may be contacted at a substrate edge. The high degree of uniformity of the layers 120 and 121 may provide a moderately high process uniformity of the electroplating process.

FIG. 1d schematically shows the semiconductor device 100 after the above-described process sequence, wherein a metal 125 is filled into the openings 122A. In some illustrative embodiments, the metal 125 is substantially comprised of copper, while, in other illustrative embodiments, any other appropriate metal or alloy of different metals may be used. In order to reliably fill the openings 122A, which may differ in diameter, in accordance with device requirements, a certain degree of overgrowth of the material 125 may be generated, wherein any excess material may be subsequently removed on the basis of CMP techniques, possibly in combination with electro-etching and the like. Depending on the material characteristics of the sacrificial layer 122, the process parameters for the removal process may be appropriately selected, wherein, for instance, the CMP performance may be enhanced compared to conventional regimes, since the layer 122 may have a significantly higher mechanical stability compared to low-k materials and especially porous low-k materials.

FIG. 1e schematically illustrates the semiconductor device 100 after the removal of the excess material, thereby also providing a substantially planar surface topography. Consequently, the device 100 comprises a plurality of metal regions 125A having a size that substantially corresponds to the design requirements. It should be appreciated that the sacrificial layer 122 may not need to exhibit specific material characteristics with respect to copper diffusion, porosity and the like, since the layer 122 is only used for defining the dimensions of the metal regions 125A, while undue copper diffusion into sensitive device areas may be reliably suppressed during the preceding manufacturing sequence by the barrier layer 120.

FIG. 1f schematically illustrates the semiconductor device 100 after the removal of the sacrificial layer 122. Hence, the device 100 comprises the isolated metal regions 125A formed above the barrier layer 120 and seed layer 121 (if employed). The removal of the sacrificial layer 122 may be accomplished on the basis of any appropriate processes, such as heat treatments with associated cleaning processes, selective etch processes and the like, depending on the material characteristics of the layer 122. For example, highly selective wet chemical etch processes for a plurality of polymer materials, or any other dielectric materials, are well-established in the art. Moreover, plasma-assisted or heat-assisted etch processes may also be used for the removal of the sacrificial layer 122.

Thereafter, exposed portions of the layers 120 and 121 may be removed by, for instance, an electrochemical etch process, wherein the structural integrity of the isolated metal regions 125A may be substantially maintained, when the material of the layers 121 and 120 is less noble compared to the metal of the regions 125A. In other illustrative embodiments, the metal regions 125A may have been formed with a certain amount of excess height such that, in a subsequent anisotropic etch process, a material removal from the top surface of the regions 125A may not substantially negatively influence the finally achieved performance of the metal regions 125A. Thus, by applying appropriate plasma-based anisotropic etch recipes, the exposed portions of the layers 120 and 121 may be removed substantially without creating any under-etching areas at the bottom of the metal regions 125A. In still other illustrative embodiments, the material removal of the regions 125A during an electrochemical etch process, in which the layers 121 and 120 may have substantially the same removal rate compared to the metal regions 125A, a corresponding reduction of height and width of the regions 125A may have been taken into consideration when selecting the dimensions of the respective openings 122A formed in the sacrificial layer 122. In other embodiments, a combination of various removal techniques may be applied for efficiently removing the barrier and the seed layers 120, 121 without unduly deteriorating the regions 125A. For instance, the seed layer 121, when comprised of substantially the same material as the regions 125A, may be provided with a reduced thickness and may therefore be efficiently removed by electro-etching without unduly affecting the regions 125A. Thereafter, the barrier layer 120 may be removed by an anisotropic etch process which may exhibit a certain degree of selectivity between the material of the barrier layer 120 and the region 125, thereby substantially reducing any material removal from the regions 125A.

FIG. 1g schematically shows the semiconductor device 100 after the above-described process sequence, wherein exposed portions of the layers 120 and 121 are removed. Consequently, the metal regions 125A now represent electrically insulated metal regions, having a reliable barrier layer 120 formed on a bottom surface thereof, when the seed layer 121 is substantially comprised of the same material as the regions 125A.

FIG. 1h schematically shows the device 100 in a further advanced manufacturing stage. A barrier or covering layer 126, comprised of any appropriate barrier and adhesion material, such as compounds of cobalt, tungsten and phosphorous and/or cobalt, tungsten and boron and the like, is formed on exposed surface portions of the regions 125A, thereby completely confining or enclosing the metal regions 125A. In one illustrative embodiment, the covering layer 126 may be formed on the basis of an electrochemical deposition process, i.e., by an electroless plating process, in which exposed surface portions of the regions 125A act as catalysts for initiating the respective deposition process. In this way, a self-aligned deposition of the covering layer 126 is achieved, thereby reliably covering any exposed surface areas of the region 125A. Thus, even any slightly damaged surface areas of the regions 125A, which may have been created during a preceding anisotropic etch process for selectively removing exposed portions of the layers 121 and 120, may be reliably covered by the layer 126, irrespective of the specific surface roughness of the regions 125A. Similarly, any surface roughness that may have been formed by a certain degree of porosity of the material of the layer 122 may also be reliably covered by the layer 126 due to the nature of the electroless deposition process. Consequently, the metal of the regions 125A is reliably confined so that any diffusion of metal into sensitive device regions and also a diffusion of oxygen or other reactive components into the regions 125A may be efficiently suppressed or reduced.

FIG. 1i schematically shows the semiconductor device 100 after the deposition or formation of a dielectric layer 127, which is comprised of a low-k dielectric material. In some illustrative embodiments, the dielectric material of the layer 127 has a relative permittivity of 3.0 or less, and even of 2.5 and less. In this case, frequently, material has to be provided in the form of a porous dielectric material, wherein, however, the reliable confinement of the metal regions 125A is still maintained due to the provision of the barrier layer 120 and the covering layer 126. Moreover, the performance of the metal regions 125A with respect to the electromigration behavior is substantially determined by the barrier layer 120 and the covering layer 126, wherein, for instance, specific alloy materials exhibit a significantly higher resistance against electromigration compared to interfaces between a dielectric barrier material, such as silicon nitride, silicon carbide, nitrogen-enriched silicon carbide and the like, as is frequently employed for bottom or top surfaces of metal lines. Consequently, the material of the layer 127 may be selected on the basis of electrical performance requirements rather than in view of electromigration properties and the capability for being covered by a conductive barrier material. For forming the dielectric layer 127, any appropriate technique may be used, such as spin-on techniques, when the material 127 is provided in the form of a polymer material having a moderately low viscosity during the application, or on the basis of any other CVD and physical vapor deposition (PVD) techniques. After the formation of the layer 127, excess material may be removed by any appropriate planarization techniques, such as CMP, etching and the like. For example, when using a CMP process for removing any excess material and planarizing the resulting surface, appropriate process parameters with low friction and a low down force may be employed, thereby maintaining the work acting against the device 100 at a low level, resulting in a reduced probability for material delamination and the formation of cracks in the dielectric layer 127.

FIG. 1j schematically shows the semiconductor device 100 after the removal of any excess material, thereby providing a metallization layer 130 comprised of the low-k dielectric material of the layer 127, which may include a porous low-k dielectric material, and the confined metal regions 125A, which are embedded into the layer 127. Hence, a further metallization layer may be formed on top of the layer 130 on the basis of substantially the same principles as are described above or as will be described later on.

As a result, the metallization layer 130 may be formed on the basis of an ultra low-k dielectric material with a reliable confinement of a highly conductive metal, such as copper, since a corresponding barrier layer or cover layer, such as the layers 120 and 126, may be formed prior to the formation of the dielectric layer 127, thereby substantially decoupling the formation process of the metal regions 125A from the respective characteristics of the material of the layer 127.

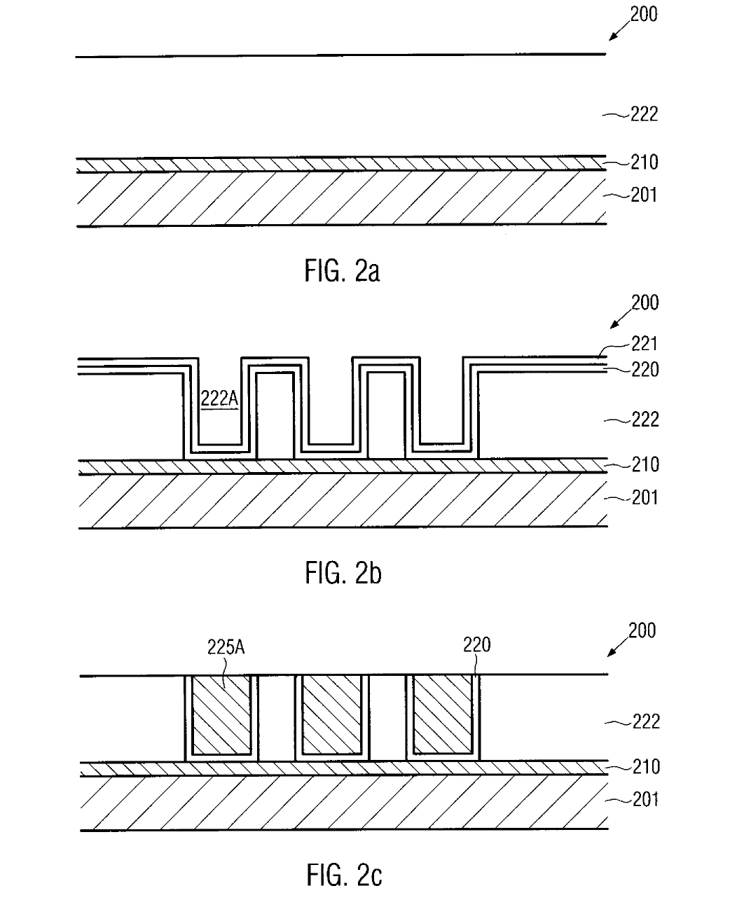

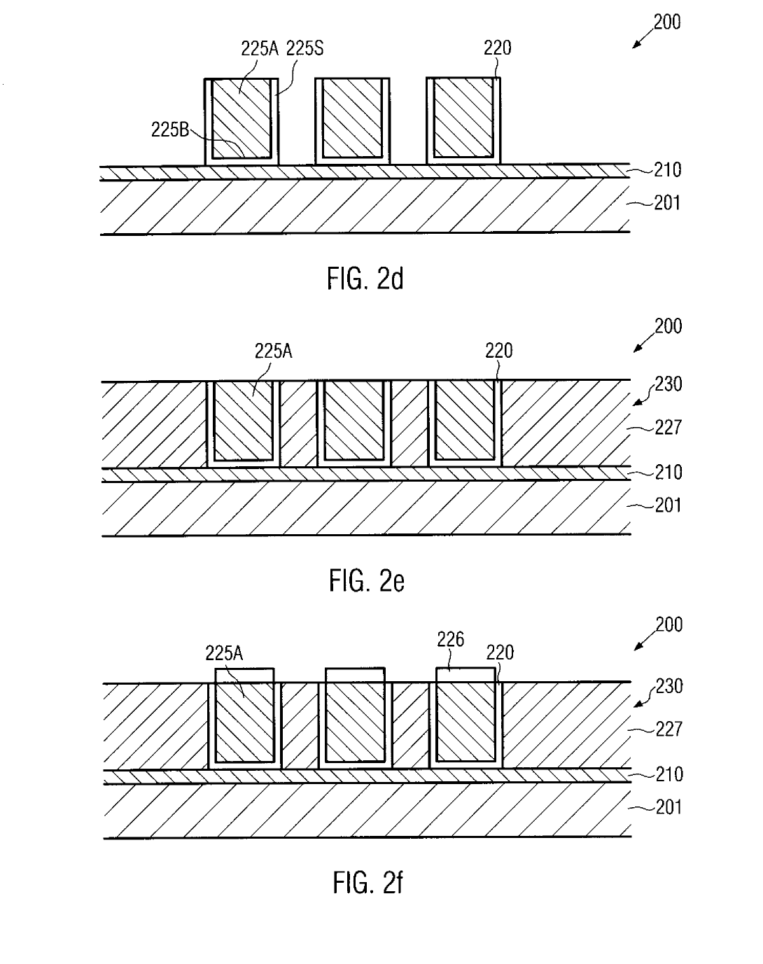

With reference to FIGS. 2a-2f, further illustrative embodiments of the present invention will now be described, wherein a barrier layer at the bottom and the sidewalls of the respective metal regions is formed in a patterned sacrificial layer in accordance with inlaid or damascene techniques.

FIG. 2a schematically shows a device 200, which may comprise a substrate 201 that may represent any appropriate carrier material for forming thereon one or more metallization layers. For example, the substrate 201 may have formed therein any circuit elements (not shown), similarly as is described with reference to the device 100, or the substrate 201 may be used for the formation of any appropriate low-k metallization architecture without additional circuit elements. Furthermore, a dielectric barrier layer 210, such as a silicon carbide layer, a nitrogen-enriched silicon carbide layer, a silicon nitride layer or any other appropriate material, may be formed above the substrate 201. A sacrificial layer 222 may be formed on the layer 210, wherein the sacrificial layer may be comprised of any appropriate material for which the same criteria apply as previously explained with reference to the layer 122. The sacrificial layer 222 may be comprised of any material that may withstand the deposition conditions of a subsequent deposition process for forming a conductive barrier layer. For example, in some illustrative embodiments, the sacrificial layer 222 may be comprised of silicon dioxide, a polymer material and the like. Regarding the formation of the sacrificial layer 222, the same processes and recipes may be used as are previously described with reference to the layer 122. After the formation of the layer 222, an appropriate patterning process may be performed, for instance on the basis of advanced lithography or on the basis of nano-imprint techniques, to form corresponding openings in the sacrificial layer 222, similarly as is described previously with reference to the device 100.

FIG. 2b schematically illustrates the semiconductor device 200 in a further advanced manufacturing stage. As shown, the sacrificial layer 222 comprises a plurality of openings 222A in which is formed a conductive barrier layer 220 followed by a seed layer 221. The barrier layer 220 may be comprised of any appropriate barrier and adhesion material, such as tantalum, tantalum nitride, tungsten nitride, cobalt/tungsten/phosphorous compounds (CoWP), cobalt/tungsten/boron compounds (CoWB) and the like. The seed layer 221 may be comprised of any appropriate material, such as copper, when a substantially copper-based metal is to be deposited into the openings 222A. The barrier layer 220 may be formed on the basis of any appropriate deposition technique, such as CVD, ALD, PVD, sputter deposition, electroless deposition, any combination thereof and the like. For example, for a plurality of barrier materials, such as tantalum and tantalum nitride, highly efficient ALD deposition techniques are established to provide a thin yet reliable continuous layer even within openings having a high aspect ratio as may be required in highly sophisticated semiconductor devices. In other embodiments, the barrier layer 220 may be formed on the basis of electroless electrochemical deposition techniques, wherein the surface of the layer 222 may be catalytically activated on the basis of well-known catalyst materials, such as palladium, platinum and the like, in order to initiate the material deposition in the subsequent electrochemical process. The seed layer 221 may also be formed on the basis of any appropriate deposition technique specified before wherein, depending on process requirements, any combination of deposition schemes may be used for the formation of the layers 220 and 221. Thereafter, or as a part of the process for forming the seed layer 221, the actual metal may be filled into the openings 222A by any appropriate electrochemical deposition technique, such as electroless deposition or electroplating, on the basis of well-established techniques to provide a substantially void-free fill behavior within the openings 222A. Thereafter, any excess material of the metal may be removed by appropriate techniques, such as CMP and/or electrochemical etch processes.

FIG. 2c schematically illustrates the device 200 after the completion of the above-described process sequence. Hence, the device 200 comprises metal regions 225A, which are confined at sidewall and bottom surfaces by the barrier layer 220. Thereafter, the sacrificial layer 222 may be selectively removed on the basis of any appropriate removal process, such as a selective etch process, wherein the barrier layer 220 and the layer 210 may provide high etch selectivity and etch controllability during a corresponding etch process. Moreover, as previously explained, any material erosion at the top of the metal regions 225A may be appropriately taken into consideration by appropriately designing the height of a sacrificial layer 222. In still other illustrative embodiments, prior to the removal of the sacrificial layer 222, a self-aligned electroless deposition process may be performed, for instance on the basis of any materials as specified above for the covering layer 126, thereby forming respective capping layers on the metal regions 225A, which may significantly reduce the liberation of metal from the regions 225A during the selective removal of the sacrificial layer 222 by substantially preventing an exposure of the metal regions 225A.

FIG. 2d schematically shows the device 200 after the removal of the sacrificial layer 222, thereby providing the metal regions 225A as isolated regions, of which at least the bottom surface 225B and the sidewall surfaces 225A are covered by the barrier layer 220 and wherein, in some embodiments, a capping layer (not shown) may be formed on top of the regions 225A, as is also shown in FIG. 2f later on.

FIG. 2e schematically illustrates the device 200 after the deposition and planarization of a low-k dielectric material to form a dielectric layer 227, wherein a metallization layer 230 comprised of the layer 227 and the metal regions 225A may have substantially the same characteristics as previously described with reference to the metallization layer 130. Moreover, a reliable confinement of the metal regions 225A is obtained, even if the material of the layer 227 is a porous low-k dielectric material, due to the formation of the layer 220 prior to the deposition of the material 227. For example, if the sacrificial layer 222 is substantially comprised of a material having a reduced porosity compared to the material of the layer 227, the barrier layer 220 may be formed in a highly continuous fashion within the respective openings 222A, thereby also providing for reliable confinement of the metal regions 225A. Consequently, a significantly reduced permittivity may be obtained on the basis of the porous low-k dielectric material, while at the same time a high degree of integrity of the metal regions 225A may be achieved.

FIG. 2f schematically illustrates the device 200 in a further advanced manufacturing stage, in which a conductive capping layer 226 may be formed on top of the metal regions 225A. The capping layers 226 may be formed in a self-aligned electroless deposition process on the basis of any appropriate material as is also specified above with reference to the covering layer 126. Thereafter, a further metallization layer may be formed on top of the layer 230, wherein similar process techniques may be used as described above.

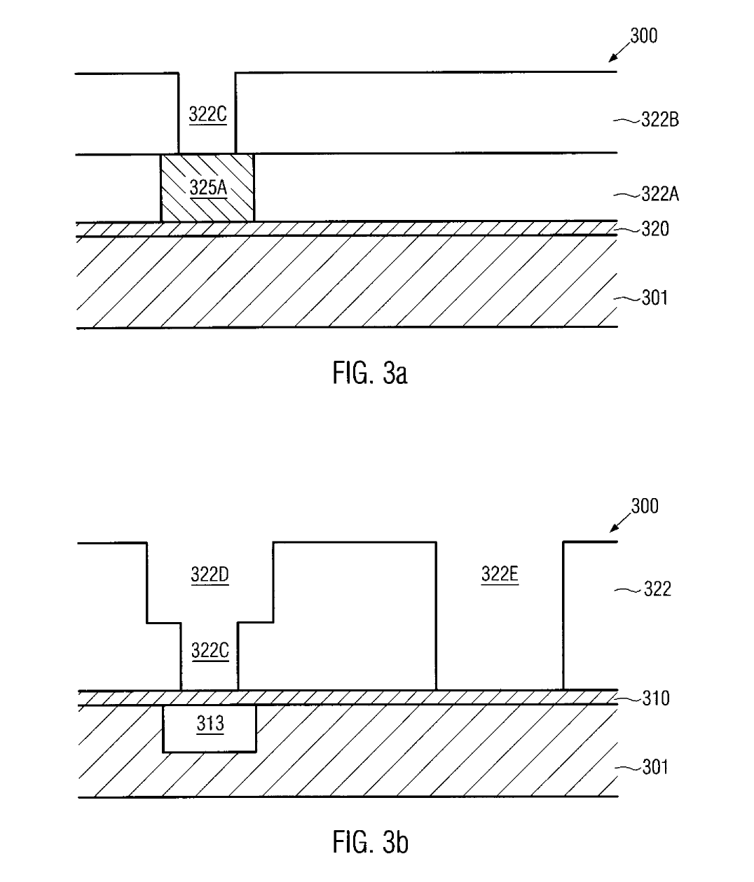

With reference to FIGS. 3a-3b, further illustrative embodiments of the present invention will now be described, wherein process complexity may be reduced. FIG. 3a schematically illustrates a device 300, which may represent any device requiring the formation of one or more metallization layers on the basis of a low-k dielectric material. The device 300 may comprise a substrate 301 above which may be formed a conductive barrier layer 320, possibly in combination with a seed layer (not shown). With respect to any characteristics of the substrate 301 and the conductive barrier layer 320, it may be referred to the corresponding components 201, 220, 101 and 120. Moreover, a first sacrificial layer 322A may be formed on the barrier layer 320, wherein a metal region 325A may be located in the first sacrificial layer 322A. Furthermore, a second sacrificial layer 322B is formed above the first layer 322A and comprises a via opening 322C connecting to the metal region 325A.

A typical process flow for forming the device 300 as shown in FIG. 3a may comprise the following processes. After the formation of any circuit elements, if provided, in and on the substrate 301, the conductive barrier layer 320 may be formed on a planarized surface of the substrate 301 on the basis of any appropriate deposition techniques as are also explained above. Thereafter, the sacrificial layer 322A may be formed by any appropriate deposition technique, such as spin-on techniques, CVD techniques and the like, wherein the layer 322A is then patterned in any appropriate manner, i.e., by lithography and etch techniques, by nano-imprint techniques and the like. Thereafter, a metal may be filled into the respective opening of the layer 322A, thereby forming the metal region 325A, wherein subsequently any appropriate process may be performed to remove any excess material of the previously deposited metal. For example, after filling in the metal, an appropriately designed CMP process may be performed to obtain a substantially planar surface topography.

Thereafter, the second sacrificial layer 322B may be formed and may be patterned on the basis of any appropriate technique. For example, the second sacrificial layer 322B may be provided as a resist mask that is patterned to provide the opening 322C in accordance with design requirements for corresponding via openings. In other illustrative embodiments, the second sacrificial layer 322B may be comprised of any other appropriate material, such as polymer materials and the like. Thereafter, a metal may be filled into the opening 322C, wherein the exposed surface of the metal region 325A may act as a seed or catalyst layer, thereby initiating an electrochemical deposition process. For example, an electroplating regime may be used, wherein currents may be provided by the barrier layer 320, possibly in combination with a respective seed layer, and the metal region 325A, thereby providing a bottom-to-top fill behavior within the opening 322C. Similarly, in an electroless deposition regime, the exposed surface of the region 325A may act as a catalyst, thereby initiating the electroless deposition of the metal, such as copper.

After filling the opening 322C, a corresponding removal and planarization process may be performed, followed by a selective removal process for removing the first and the second sacrificial layers 322B, 322A, wherein one or more removal processes may be employed. For example, if the second sacrificial layer 322B is provided in the form of a resist mask, any well-established plasma-assisted removal processes may be used, followed by a correspondingly designed etch process for removing the layer 322A. In still other embodiments, the first and second layers 322A, 322B may be comprised of substantially the same material and hence these layers may be removed in a common removal process. After the removal of the layers 322A, 322B, a corresponding metallization structure comprised of the metal regions 325A and corresponding metal vias is obtained, which may be subsequently embedded into a low-k dielectric material on the basis of processes as previously described with reference to the layers 127 and 227.

Thereafter, a further process sequence may be performed to form a next metallization layer comprising a layer of metal lines connecting to vias formed in the openings 322C and with a further via layer for connecting to a further metallization layer. Thus, a highly efficient technique may be provided to form a low-k dielectric layer stack including metal lines and vias with reduced process complexity, since the formation of the low-k dielectric material and/or the removal of the sacrificial layers 322A, 322B may be accomplished in a single process.

FIG. 3b schematically illustrates the device 300 according to other illustrative embodiments. In this embodiment, the device 300 may comprise a metal region or contact region 313 that is formed above the substrate 301. Moreover, a dielectric barrier layer 310 or any other appropriate material, such as a layer comprised of silicon nitride, silicon carbide, nitrogen-enriched silicon carbide and the like, may be provided above the metal or contact region 313. Furthermore, the sacrificial layer 322 may be provided in the form of a single continuous layer or may be provided in the form of a layer stack including an intermediate etch stop layer or etch indicator layer (not shown). The sacrificial layer 322 may be patterned in accordance with well-established dual damascene regimes, in which a via may be formed first and afterwards a trench may be patterned or wherein a trench may be formed first and a via may be patterned afterwards. Consequently, the sacrificial layer 322 may comprise a trench 322D and the respective via opening 322C connected thereto. In illustrative embodiments, additionally, a moderately large trench or other opening 322E may be formed in an appropriate device region to provide increased stability of the resulting metallization structure. After the patterning of the sacrificial layer 322 on the basis of established lithography techniques or nano-imprint techniques, depending on the material characteristics of the layer 322, the further processing may be continued by the deposition of a conductive barrier layer and a seed layer on the basis of any appropriate deposition regime, as is also described above with reference to embodiments illustrated in FIGS. 2a-2f. In still other embodiments, the layer 310 may be provided in the form of a conductive barrier layer and the further deposition of metal into the openings 322D, 322C and 322E may be performed in substantially the same manner as previously described with reference to FIGS. 1a-1j and 3a. Consequently, depending on the desired strategy, the openings in the sacrificial layer 322 may be filled with a metal, thereby forming a via and a metal line in a common fill process. Moreover, the opening 322E may also be reliably filled with metal, thereby providing the required mechanical stability when the sacrificial layer 322 is removed and subsequently replaced by a low-k dielectric material. In this regime, an appropriate isotropic deposition regime for the low-k dielectric material may be used to also provide a dielectric material in areas shadowed by a corresponding metal line formed in the trench 322D. Consequently, the corresponding metallization structure may be formed in accordance with well-established process strategies, thereby providing high process efficiency, wherein the replacement of the sacrificial layer 322 by an appropriate low-k dielectric material may be accomplished by providing additional dummy trenches or vias, such as the opening 322E.

As a result, the present invention provides a technique that enables the formation of metallization layers with significantly reduced parasitic capacitance between adjacent metal regions due to the provision of low-k dielectric materials having a dielectric constant well below 3.0, wherein even a high degree of porosity may not adversely affect the overall performance with respect to electromigration and metal diffusion. The reliable confinement of the metal by a conductive barrier material may be accomplished by providing the conductive barrier material on the basis of any appropriate selective deposition recipes prior to the actual deposition of the low-k dielectric material. In illustrative embodiments, self-aligned electroless deposition processes and/or silylation processes may be used to reliably cover exposed metal portions prior to or after the replacement of the sacrificial layer by a corresponding low-k dielectric material. Moreover, a patterned sacrificial layer may be used to enable the employment of standard inlaid or damascene techniques, thereby providing the prerequisites for technology nodes of 45 nm and less.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming an opening in a sacrificial layer formed above a substrate of a semiconductor device;
forming a metal region in said opening;
removing said sacrificial layer; and
depositing a low-k dielectric material to embed said metal region in said low-k dielectric material.

2. The method of claim 1, further comprising forming a conductive layer prior to forming said sacrificial layer, wherein said opening is formed to expose said conductive layer.

3. The method of claim 2, wherein said metal region covers a portion of said conductive layer, further comprising removing a non-covered portion of said conductive layer prior to depositing said low-k dielectric material.

4. The method of claim 3, wherein said conductive layer is removed by an electrochemical removal process.

5. The method of claim 4, wherein a material composition of said conductive layer is selected to have a higher removal rate compared to the material of said metal region.

6. The method of claim 2, wherein forming said conductive layer comprises forming a conductive barrier layer and a seed layer.

7. The method of claim 3, further comprising forming a conductive cover layer on exposed surfaces of said metal region after removing said non-covered portion of said conductive layer and prior to depositing said low-k dielectric material.

8. The method of claim 7, wherein said conductive cover layer is formed by an electrochemical deposition technique.

9. The method of claim 1, further comprising forming a conductive barrier layer after forming said opening and prior to forming said metal region.

10. The method of claim 9, wherein said conductive barrier layer is formed by at least one of physical vapor deposition, chemical vapor deposition, atomic layer deposition and electroless plating.

11. The method of claim 9, further comprising forming a seed layer on said conductive barrier layer.

12. The method of claim 9, wherein said sacrificial layer is removed selectively to said metal region and said conductive barrier layer.

13. The method of claim 9, further comprising removing excess material of said low-k dielectric material to expose a top surface of said metal region.

14. The method of claim 13, further comprising forming a conductive capping layer on said exposed top surface.

15. The method of claim 14, wherein said conductive capping layer is formed by an electrochemical deposition technique.

16. The method of claim 1, wherein said opening is formed by lithography and etching.

17. The method of claim 1, wherein said opening is formed by an imprint technique.

18. A method, comprising:
forming a metal region above a substrate of a semiconductor device, said metal region having a conductive barrier layer formed on at least a sidewall surface of said metal region; and
forming a low-k dielectric layer on said previously formed conductive barrier layer.

19. The method of claim 18, wherein said metal comprises copper.

20. The method of claim 19, wherein forming said metal region comprises filling in a metal in an opening formed in a sacrificial layer, removing said sacrificial layer and forming said conductive barrier layer.

21. The method of claim 18, wherein forming said metal region comprises forming an opening in a sacrificial layer, forming said conductive barrier layer in said opening and filling said opening with a metal.

22. The method of claim 18, wherein said low-k dielectric layer is comprised of a porous material having a relative permittivity of approximately less than 3.0.
